(19) United States
(12) Patent Application Publication
(10) Pub. No.: US 2022/0404393 A1
(43) Pub. Date: Dec. 22, 2022

(54) Testing Device for a Medium Voltage Starter

(71) Applicants: Darryl Vance, Wilmer, AL (US); Regina Vance, Wilmer, AL (US)

(72) Inventors: Darryl Vance, Wilmer, AL (US); Regina Vance, Wilmer, AL (US)

(21) Appl. No.: 17/841,796

(22) Filed: Jun. 16, 2022

Related U.S. Application Data
(60) Provisional application No. 63/212,878, filed on Jun. 21, 2021.

(51) Int. Cl. G01R 1/02; G01R 31/34

(52) U.S. Cl. CPC G01R 1/025; G01R 31/34

(57) ABSTRACT

A testing device for testing a medium voltage starter or breaker and method of use. The testing device is configured to test starter motors in the 2,300 volts to 13,800 volts range while protecting the technician from high voltages. The testing device is electrically connectable to a variety of different medium voltage starter motors via an umbilical connector harness adapted for each specific starter. A tester control board is organized to indicate the functionality of the medium voltage starter electrical components. The control board is used to isolate circuits in open and closed positions and visual indicators are used to verify proper operation of the starter coil, primary contacts, and auxiliary contacts.

### CROSS-REFERENCE TO RELATED APPLICATION

The present application claims priority to, and the benefit of, U.S. Provisional Application No. 63/212,878, which was filed on Jun. 21, 2021, and is incorporated herein by reference in its entirety.

### FIELD OF THE INVENTION

The present invention generally relates to a testing device for starters, and more specifically to a device for testing the wiring, the coil, and all electrical components of a medium voltage starter. Accordingly, the present specification makes specific reference thereto. However, it is to be appreciated that aspects of the present invention are also equally amenable to other like applications, devices and methods of manufacture.

### BACKGROUND

Technicians may be unable to test the wiring and all electrical components onboard different medium voltage starters from different manufacturers fully and safely. The technicians may be inadvertently exposed to high voltages which are within the restricted boundary per NFPTA 70E. Downtime of starter motors will be dramatically increased without a safe and effective testing system.

A medium voltage starter is an apparatus that applies a reduced voltage to a medium voltage alternating or direct current motor to allow for soft starting and stopping, limiting the inrush current, and reducing the effects of water hammer in pumping or other systems. Medium voltage motors are used in a wide variety of industries in which heavy loads are moved or work is carried out in conjunction with particularly complex application.

A soft starter is an electronic motor controller used on three phase medium voltage squirrel cage induction motors. During motor starting, the soft starter controls the voltage or current supplied to the motor. Motor start performance is optimized by reducing the total start current while optimizing the torque produced by the motor, thereby prolonging the working life of the motor.

Medium voltage control equipment starts and stops electrical loads and is used to drive productivity, process performance and energy savings for motors. Medium voltage control equipment includes a variety of starters and adjustable frequency drives that generally range from approximately 2,300 to approximately 13,800 volts. The motor loads can be as low as approximately 50 horsepower, with the upper limit of approximately 8,000 horsepower, depending on voltage. Typically, this equipment controls motors used in applications, such as pumping, fans and chillers. Transformers and capacitors can also be energized by medium voltage control as well as other equipment powering oil and gas, water and wastewater, utility generation and other applications.

A starter is a device used to initiate a motor's operation under its own power. Electrical starters are commonly used for this purpose. A small motor can be started by simply connecting it to power. A larger motor requires a specialized switching unit called a motor starter or motor contactor. When energized, a direct online starter immediately connects the motor terminals directly to the power supply. In smaller sizes a motor starter is a manually operated switch. Larger motors, or those requiring remote or automatic control, use magnetic contactors. Very large motors running on medium voltage power supplies (thousands of volts) may use power circuit breakers as switching elements. These electrical components are subject to failure and require regular testing.

Motor testing assesses the integrity of the motor through the use of computer-supported equipment or tools that monitor trends within the motor. The purpose of motor testing is to find existing problems and prevent unnecessary failure or downtime. Specific to electric motors, motor testing evaluates static parameters like insulation, wire damage and electrical current leakage, as well as more dynamic parameters such as distortion, temperature fluctuations and balance.

Tools for starter motor testing include digital multi meters which combine multiple single-function tools such as a voltmeter, ammeter, and ohmmeter. An ammeter measures the current in a circuit by assessing the strength of the magnetic field around a conductor. A megohmmeter is a type of ohmmeter used to measure the electrical resistance of insulators. A non-contact thermometer is a motor testing tool that measures temperature at a single point from a safe distance. Power quality analyzers are more expensive testing devices that can test for multiple features. However, medium voltage starters have many different designs and there is no single testing device that can be used for a wide variety of these starters.

Accordingly, there is a great need for a new and improved device that allows for testing of a medium voltage starter. There is also a need for a device that allows users to easily solve an electrical issue without being put in danger of high voltage accidental contact. There is also a need for a way that an employee can maintain a safe distance to test the components and reduce downtime of motors and equipment. Further, there is a need for a device that allows for full testing of wiring and all electrical components of a medium voltage starter in a matter of seconds.

In this manner, the improved medium voltage starter tester of the present invention accomplishes all of the forgoing objectives, thereby providing an easy solution for testing of a medium voltage starter. A primary feature of the present invention is a waterproof briefcase and a button for the user to test the circuits and operate the starter. The testing device utilizes light indicators that will offer information to the user so any problems can be corrected. Finally, the improved medium voltage starter tester of the present invention can improve the safety of the technician while testing the wiring and all the electrical components of a medium voltage starter.

### SUMMARY

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The subject matter disclosed and claimed herein, in one embodiment thereof, comprises a testing device. The testing device is configured to bench test a variety of different medium voltage starters. The medium voltage starters all typically range from approximately 2,300 to approximately 13,800 volts. The testing device is configured to test all wiring, the coil, the primary and auxiliary contacts, or any other electrical components located on board the medium voltage starter.

The testing device comprises a housing, a power cord, an umbilical connecter harness, and a control board. The control board is retained within the housing. The housing comprises a power inlet for connecting the power cord to a power source and powering the control board. The umbilical connector harness electrically connects the testing device to the medium voltage starters.

The control board is configured to indicate functionality of a plurality of electrical components of the medium voltage starter. The plurality of electrical components comprise a coil, a plurality of primary contacts, and a plurality of auxiliary contacts. The control board comprises an umbilical connector harness hookup. The umbilical connector harness hookup is configured to engage a control board end of the umbilical connector harness. A starter connecter end of the umbilical connector harness is connectable to the medium voltage starter electrically connecting the control board to the medium voltage starter. The umbilical connector harness hookup may comprises a plurality of ports, each configured for a different medium voltage starter.

The control board further comprises a circuit isolator. The circuit isolator is configured to open and close a circuit. The circuit isolator may comprise a plurality of isolator switches to open and close a plurality of circuits. The control board further comprises a function test indicator component. The function test indicator component comprises a plurality of indicator lights. The plurality of indicator lights are configured to visually indicate an open or closed status of a coil, a plurality of primary contacts, and a plurality of auxiliary contacts of the medium voltage starter.

The subject matter disclosed and claimed herein, in another embodiment thereof, comprises a method of bench testing a medium voltage starter. The method begins by isolating the medium voltage starter from a high voltage source. A testing device comprising a control board configured to verify proper operation of a coil, a plurality of primary contacts, and a plurality of auxiliary contacts of the medium voltage starter is then provided. The medium voltage starter is then electrically connected to the testing device via an umbilical connector harness.

Once connected, the testing device is powered via a power cord connected to a power source and a status of a normally closed contact of the medium voltage starter via a visual indicator on the control board is verified. A normally open contact of the medium voltage starter is then isolated via a switch of the testing device. Then, a status of the normally open contact of the medium voltage starter is verified via a visual indicator on the control board. Additionally, a status of a coil or other components of the medium voltage starter may also be verified via a visual indicator on the control board.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective overhead view of one embodiment of a testing device of the present invention for testing a medium voltage starter in accordance with the disclosed architecture.

FIG. 2 illustrates a perspective side view of a housing of the testing device of the present invention for testing a medium voltage starter in accordance with the disclosed architecture.

FIG. 3 illustrates a perspective overhead view of a control board of the testing device of the present invention for testing a medium voltage starter in accordance with the disclosed architecture.

FIG. 4 illustrates a schematic view of the testing device of the present invention for testing a medium voltage starter in accordance with the disclosed architecture.

FIG. 5 illustrates a schematic view of the testing device of the present invention for testing a medium voltage starter in accordance with the disclosed architecture.

FIG. 6 illustrates a perspective overhead view of the control board of the testing device of the present invention for testing a medium voltage starter in accordance with the disclosed architecture.

FIG. 7 illustrates a schematic view of the testing device of the present invention for testing a medium voltage starter in accordance with the disclosed architecture

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They do not intend as an exhaustive description of the invention or do not limit the scope of the invention. Additionally, an illustrated embodiment need not have all the aspects or advantages shown. Thus, in other embodiments, any of the features described herein from different embodiments may be combined.

The present invention, in one exemplary embodiment, is a medium voltage starter testing device for allowing a user to fully test the wiring and all electrical components of a starter in a matter of seconds. The device employs a plurality of test box indication lights that provides information to the user to solve an electrical issue. The device is portable and allows the user to perform the testing away from any hazardous voltage. The device will be housed in a waterproof briefcase and will also have a button for the user to test the circuits and operate the starter.

A motor starter generally uses an electromagnetically operated set of contacts to start and stop a connected motor load. A control circuit with momentary contact devices connected to the coil of the magnetic motor starter performs this start and stop function. A typical medium voltage motor starter is made up of the following components: a set of stationary contacts, a set of movable contacts, pressure springs, a solenoid coil, a stationary electromagnet, a set of magnetic shading coils, and the moving armature. A controller is any switch or device that is normally used to start and stop a motor by making and breaking the motor circuit current. These are all components that require testing.

The testing device of the present invention is used to test and troubleshoot medium voltage starters and breakers (2300v to 13,800v). The testing device is customized based on each starter manufacturer product. This custom design test device will save time and protect technicians by isolating the medium voltage. This test device will supply the low voltage for testing all the internal circuits on board the starter or breaker. Low voltage level typically will be 220v, 110v, 24 vdc or 48 vdc.

A switch is used as main control power on/off. Indicating lights provide information to the user if the auxiliary contacts are working properly and aids in troubleshooting. Push buttons or switches are used to close the starter or breaker so the user can verify proper operation of the closing circuit and test contact resistance across the main contacts. The connection between the test box and the starter or breaker varies based on the manufacturer. Whatever connection is on the electrical device is what will be used and designed to properly connect based on the factory schematic. This device can be used on the test bench or while the starter is installed, and the medium voltage is isolated. The best use of this device is during maintenance activities.

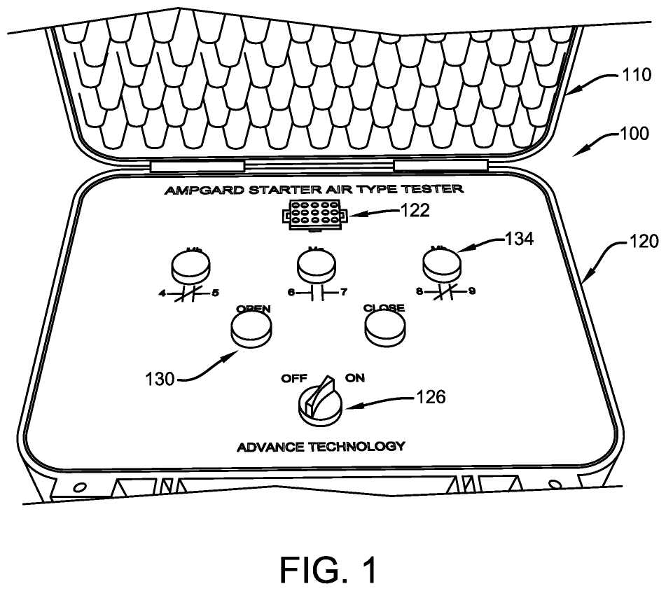

Referring initially to the drawings, FIGS. 1-7 illustrate a testing device 100. The testing device 100 is configured to test a medium voltage starter 10 or a breaker. The testing device 100 is configured to test all wiring, the coil, and the primary and auxiliary contacts located on board the motor starter 10. The testing device 100 is customizable to be able to test a variety of medium voltage starters, each with a different electrical connection, such as, but not limited to Westinghouse LF starters, Eaton SJ and SL starters , Allen Bradley 1502 starter, and Allen Bradley Intellivac Module. The testable medium voltage starters typically range from approximately 2,300 to approximately 13,800 volts.

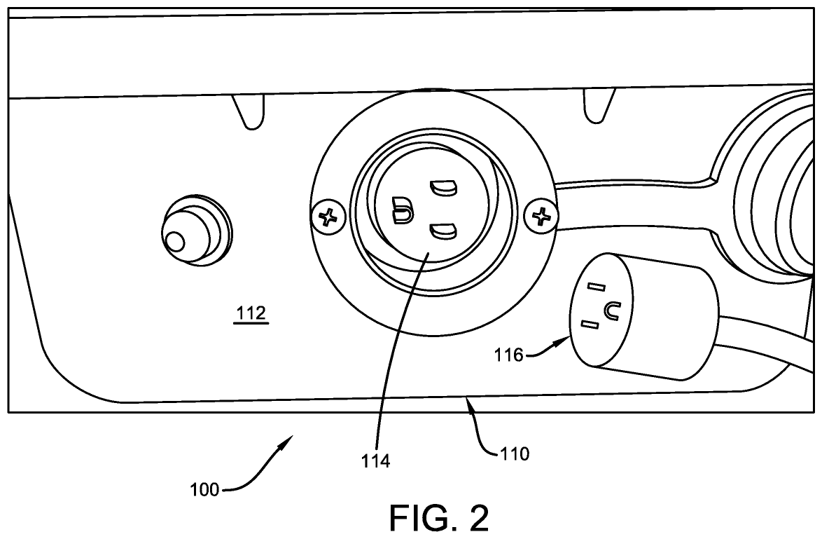

As illustrated in FIGS. 1-3, the testing device 100 comprises a housing 110, a power cord 116, an umbilical connecter harness 150, and a control board 120. As illustrated in FIG. 2, the housing 110 comprises an exterior casing 112 and a power inlet 114. The housing 110 is generally waterproof or weatherproof and is constructed from a durable plastic material, such as polypropylene, to protect the control board 120. The power cord 116 connects the power inlet 114 to a power source and provides power to the control board 120. The power cord 116 is typically a 120 volt or similar power cord.

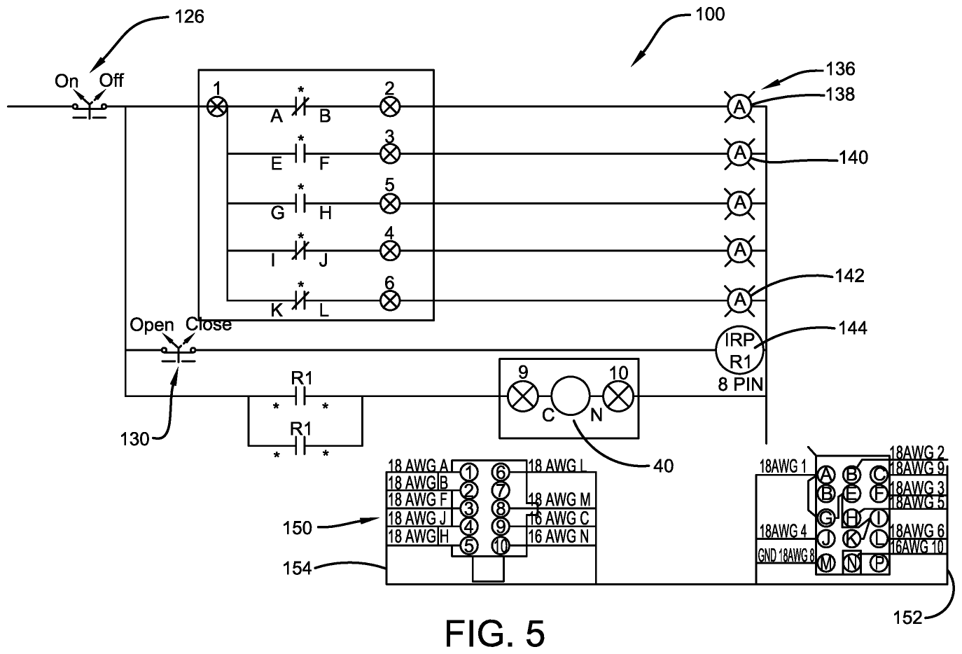

The control board 120 is retained within and protected by the housing 110. The control board 120 is configured to indicate functionality of a plurality of electrical components of the medium voltage starter 10. As illustrated in FIG. 5, the plurality of electrical components may comprise a coil 40, a plurality of primary contacts 20, and a plurality of auxiliary contacts 10, although this is not meant as a limitation as any testable electrical component of a medium voltage starter 10 may be included as well.

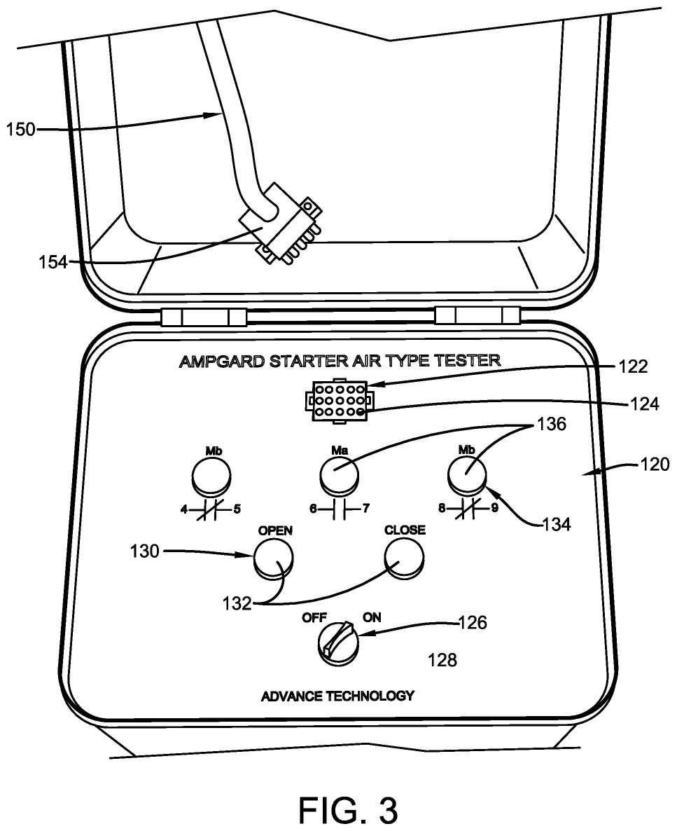

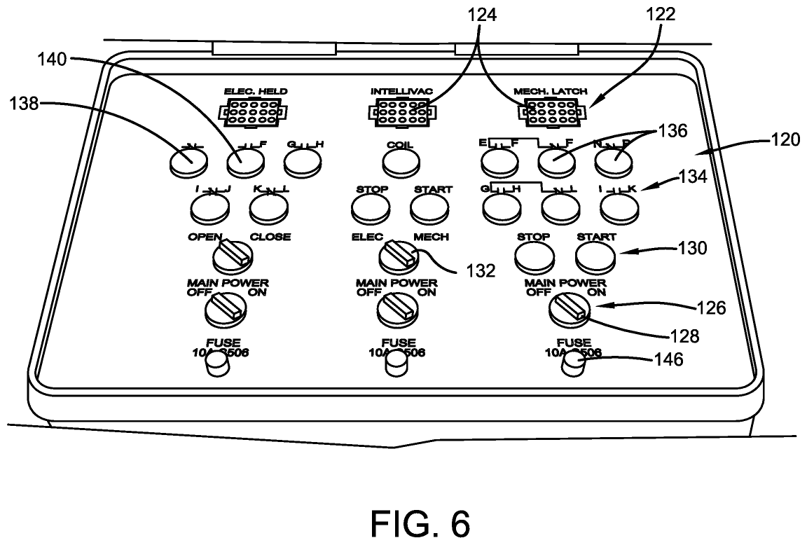

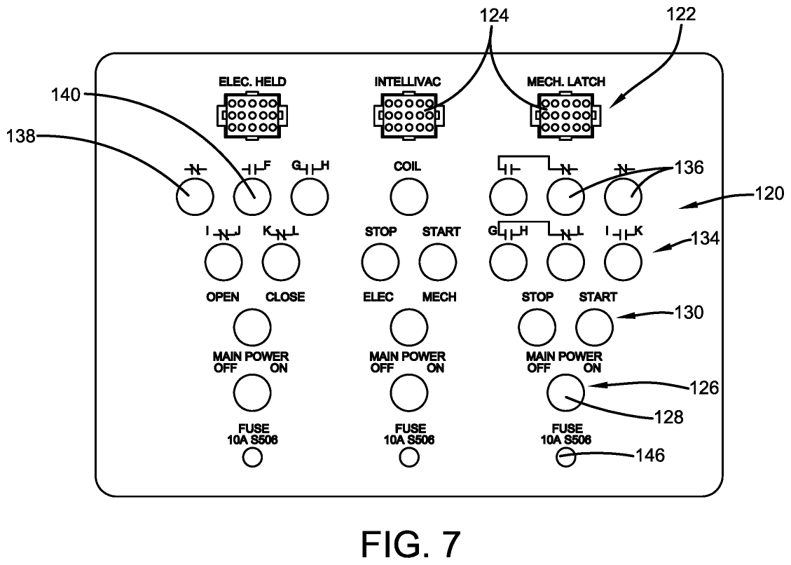

As illustrated in FIG. 3, the control board 120 comprises an umbilical connector harness hookup 122. The umbilical connector harness 150 electrically connects the testing device 100 to the medium voltage starter 10. The umbilical connector harness hookup 122 is configured to engage a control board end 154 of the umbilical connector harness 150. A starter connecter end 152 of the umbilical connector harness 150 is connectable to the medium voltage starter 10 electrically connecting the control board 120 to the medium voltage starter 10. As illustrated in FIGS. 6 and 7, the umbilical connector harness hookup 122 may comprises a plurality of ports 124. Each of the plurality of ports 124 is specifically adapted and configured for a different brand or type of medium voltage starter 10. The plurality of ports 124 are interchangeable and are customizable based on the types of starters to be tested.

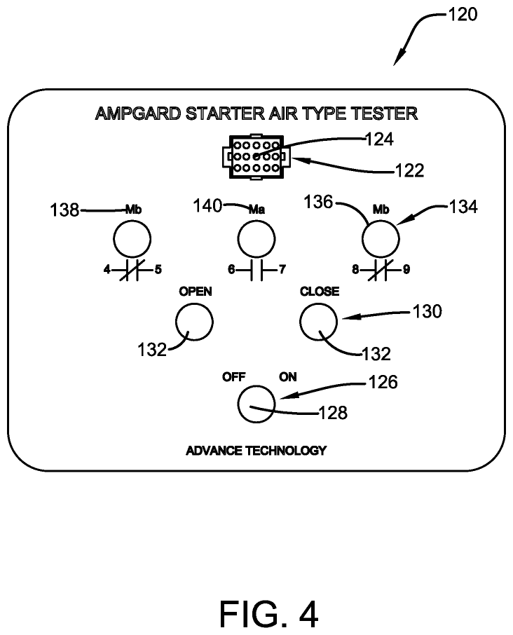

As illustrated in FIGS. 3 and 4, the control board 120 further comprises a power control component 126. The power control component 126 is a button or similar mechanical or electrical switch configured to allow power to flow from the power cord 116 to the downstream components of the control board 120 as discussed infra. As illustrated in FIGS. 6 and 7, the power control component 126 may comprises a plurality of power switches 128. The plurality of power switches 128 are adapted to allow the flow of power to a subset of the downstream components of the control board 120.

Returning to FIGS. 3-5, the control board 120 further comprises a circuit isolator 130. The circuit isolator 130 is configured to open and close a circuit of the medium voltage starter 10. The circuit isolator 130 may be a mechanical or electrical switch. As illustrated in FIGS. 6 and 7, the circuit isolator 130 may comprise a plurality of isolator switches 132. The plurality of isolator switches 132 are used to open and close a plurality of different circuits of the medium voltage starter 10, such as the coil 40, the plurality of primary contacts 20, and the plurality of auxiliary contacts 10.

Returning to FIGS. 3-5, the control board 120 further comprises a function test indicator component 134. The function test indicator component 134 comprises a plurality of indicator lights 136. The plurality of indicator lights 136 may be LED or similar low voltage lamps. The plurality of indicator lights 136 are configured to visually indicate an open or closed status of the coil 40, the plurality of primary contacts 20, and the plurality of auxiliary contacts 30 of the medium voltage starter 10. The plurality of indicator lights 136 may visually indicate the status via a flashing pattern, a steady pattern, a blinking pattern, a plurality of different colors, or the like.

As illustrated in FIGS. 3-7, the plurality of indicator lights 136 may comprise a plurality of primary contact indicators 138, a plurality of auxiliary contact indicators 140, and a plurality of coil indicators 142. While not shown, it is contemplated that the plurality of indicator lights 136 may further comprise indicators for additional testable electrical components of the medium voltage starter 10 as the control board 120 is customizable depending on the brand of the medium voltage starter 10. The power control component 126 controls the flow of power to the circuit isolator 130 and the function test indicator component 134.

As illustrated in FIG. 5, the control board 120 may further comprise an interposing relay 144. The interposing relay 144 is used to limit current flow for safety. The interposing relay 144 is used to carry the large current of energizing the coil 40. The power control component 126 is not rated for enough current to energize the coil. As illustrated in FIG. 7, the control board 120 may further comprise a plurality of fuses 146. FIGS. 6 and 7 illustrate a control board 120 configured to test three different medium voltage starters 10. There are three umbilical connector harness hookups 124, three second circuit isolator 132, and three function test indicator component 134, each set of components controlled by a separate power switch 128. This allows the user to test multiple brands of different medium voltage starters 10 with a single testing device 100.

Alternatively, the control board 120 may be a touch screen device with soft (or software) switches for controlling the power control component 126, circuit isolator 130, and function test indicator component 134 instead of mechanical or physical switches. Further, the indicator lights could be virtual indicator lights on the touch screen device. The touch screen device may also have a soft screen, such as a VA screen, and a hard screen, such as a IPS hard screen.

The subject matter disclosed and claimed herein, in another embodiment thereof, comprises a method of bench testing a medium voltage starter 10. The medium voltage starter 10 may also be tested as installed at the MCC with high voltage isolated. The method begins by isolating the medium voltage starter 10 from a high voltage source. A testing device 100 comprising a control board 120 configured to verify proper operation of a coil 40, a plurality of primary contacts 20, and a plurality of auxiliary contacts 30 of the medium voltage starter 10 is then provided. Once isolated from the high voltage, the medium voltage starter 10 is then electrically connected to the testing device 100 via an umbilical connector harness 150 adapted specifically for the brand of the medium voltage starter 10.

Once connected to the medium voltage starter 10, the testing device 100 is powered via a power cord 116 connected to a power source. Once connected to the power source, a status of a normally closed contact of the medium voltage starter 10 is verified via a visual indicator of a function test indicator component 134 on the control board 120. A normally open contact of the medium voltage starter 10 is then isolated via a circuit isolator switch 130 of the testing device 100. Then, a status of the normally open contact of the medium voltage starter 10 is verified via a visual indicator of the function test indicator component 134 on the control board 120. Additionally, a status of the coil 40 or other components of the medium voltage starter 10 may also be verified via a visual indicator of the function test indicator component 134 on the control board 120.

In an exemplary testing scenario, the medium voltage starter 10 should close and the indicator lights should go out on the normally closed contacts and the indicating lights on the normally open contacts should illuminate. After the medium voltage starter 10 has been tested, the user may push the open push button or selector switch and you have verified the medium voltage starter 10 is working properly. If any indicating lights fail to illuminate, the technician may use a meter to test the contacts on board the medium voltage starter 10. Factory wire numbers may be printed on the housing 110 to aid in repair. If a coil 40 fails to energize, the technician may verify wiring on the medium voltage starter 10 and make sure the coil 40 has not failed. When the contacts are closed the indicating light will be on steady. If the coil 40 has failed, the indicating light will remain in the off state.

It is contemplated that the testing device 100 constructed in accordance with the present invention will be tailored and adjusted by those of ordinary skill in the art to accommodate various levels of performance demand imparted during actual use. Accordingly, while this invention has been described by reference to certain specific embodiments and examples, it will be understood that this invention is capable of further modifications. This application is, therefore, intended to cover any variations, uses or adaptations of the invention following the general principles thereof, and including such departures from the present disclosure as come within known or customary practice in the art to which this invention pertains and fall within the limits of the appended claims.

Notwithstanding the forgoing, the testing device 100 of the present invention and its various structural components can be any suitable size, shape, and configuration as is known in the art without affecting the overall concept of the invention, provided that it accomplishes the above stated objectives. One of ordinary skill in the art will appreciate that the shape and size of the testing device 100 and its various components, as show in the FIGS. are for illustrative purposes only, and that many other shapes and sizes of the testing device 100 are well within the scope of the present disclosure. Although dimensions of the testing device 100 and its components (i.e., length, width, and height) are important design parameters for good performance, the testing device 100 and its components may be of any shape or size that ensures optimal performance during use and/or that suits user need and/or preference.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A testing device for testing a medium voltage starter, the testing device comprising:
a housing;
a control board retained within the housing;
a power cord connectable to the control board; and
an umbilical connector harness for electrically connecting the testing device to the medium voltage starter; and
wherein the control board is configured to indicate functionality of a plurality of electrical components of the medium voltage starter.

2. The testing device of claim 1, wherein the testing device is configured to test a medium voltage starter ranging from 2,300 volts to 13,800 volts.

3. The testing device of claim 1, wherein the housing is waterproof.

4. The testing device of claim 1, wherein the control board is configured to indicate functionality of a coil, a plurality of primary contacts, and a plurality of auxiliary contacts of the medium voltage starter.

5. The testing device of claim 1, wherein the control board comprises an umbilical connector harness hookup configured to engage the umbilical connector harness.

6. The testing device of claim 1, wherein the control board comprises a circuit isolator configured to open and close a circuit.

7. The testing device of claim 6, wherein the circuit isolator is a mechanical switch.

8. The testing device of claim 1, wherein the control board comprises a function test indicator component.

9. The testing device of claim 8, wherein the function test indicator component comprises a plurality of indicator lights.

10. The testing device of claim 9, wherein the plurality of indicator lights indicate an open or closed status of a coil, a plurality of primary contacts, and a plurality of auxiliary contacts of the medium voltage starter.

11. The testing device of claim 10, wherein the control board comprises an interposing relay to limit current flow.

12. A testing device for testing a medium voltage starter, the testing device comprising:
a housing comprising a power inlet;
a control board retained within the housing;
a power cord connectable to the power inlet; and
an umbilical connector harness for electrically connecting the control board to the medium voltage starter; and
wherein the control board comprises an umbilical connector harness hookup, a circuit isolator, and a function test indicator component, and is configured to indicate functionality of a coil, a plurality of primary contacts, and a plurality of auxiliary contacts of the medium voltage starter.

13. The testing device of claim 12, wherein the testing device is configured to test a medium voltage starter ranging from 2,300 volts to 13,800 volts.

14. The testing device of claim 12, wherein the function test indicator component comprises a plurality of indicator lights.

15. The testing device of claim 12, wherein the function test indicator component is configured to visually signal an open or closed status of the coil, the plurality of primary contacts, and the plurality of auxiliary contacts of the medium voltage starter.

16. The testing device of claim 12, wherein the control board further comprises a second umbilical connector harness hookup, a second circuit isolator, and a second function test indicator component.

17. The testing device of claim 12, wherein the control board further comprises an interposing relay to limit current flow.

18. The testing device of claim 12, wherein the control board further comprises at least one fuse.

19. A method of bench testing a medium voltage starter comprising:
isolating the medium voltage starter from a high voltage source;
providing a testing device comprising a control board configured to verify proper operation of a coil, a plurality of primary contacts, and a plurality of auxiliary contacts of the medium voltage starter;
electrically connecting the testing device to the medium voltage starter via an umbilical connector harness;
verifying a status of a normally closed contact of the medium voltage starter via a visual indicator on the control board;
isolating a normally open contact of the medium voltage starter via a switch of the testing device; and
verifying a status of the normally open contact of the medium voltage starter via a visual indicator on the control board.

20. The method of claim 19 further comprising the step of verifying a status of a coil of the medium voltage starter via a visual indicator on the control board.
